(19) United States
(12) Patent Application Publication
(10) Pub. No.: US 2021/0020722 A1
(43) Pub. Date: Jan. 21, 2021

(54) ARRAY SUBSTRATE AND DISPLAY DEVICE USING ARRAY SUBSTRATE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Jie LIU, Wuhan, Hubei (CN)

(21) Appl. No.: 16/756,510

(22) PCT Filed: Dec. 26, 2018
(86) PCT No.: PCT/CN2018/124063

§ 371 Date: Apr. 16, 2020

(30) Foreign Application Priority Data
Oct. 18, 2018 (CN) 201811214286.8

(51) Int. Cl. H01L 27/32

(52) U.S. Cl. CPC H01L 27/3276

(57) ABSTRACT

An array substrate and a display device using the array substrate are provided. The array substrate includes: a gate line; a gate insulating layer covering the gate line; an active layer disposed on the gate insulating layer; an annular source line disposed on the active layer; a circular drain line disposed on the active layer, wherein a center of the circular drain line coincides with a center of the annular source line; and an elevation layer having an annular elevation block and a circular elevation block. The annular elevation block supports between the annular source line and the active layer, and the circular elevation block supports between the circular drain line and the active layer. The present disclosure has the following advantages. By using a closed annular gate and a closed annular active layer, output current is ensured to be stable. At the same time, by using a concave-convex source/drain electrode design, parasitic capacitance between a source/drain electrode and a gate electrode is reduced, having higher controllability.

### FIELD OF INVENTION

The present disclosure relates to a technical field of liquid crystal displays, and more particularly to an array substrate and a display device using the array substrate.

### BACKGROUND OF INVENTION

Principles of organic light-emitting diode (OLED) display devices are that currents flow through organic light-emitting materials, carriers transport between organic materials and recombine to emit light of various wavelengths. Therefore, OLED display devices are driven by currents. Amounts of luminescence of organic light-emitting materials are controlled by magnitudes of currents, which requires OLED display devices to accurately and stably control driving currents.

As shown by equation 1:

$${I}_{DS} = \frac{1}{2} {μ}_{n} {C}_{ox} \frac{W}{L} {( {V}_{Gs} - {V}_{th} )}^{2} ,$$

stable output currents may be obtained using current characteristics of array substrates in saturation regions. Because output currents at this time are independent of magnitudes of output voltages V_{DS} of array substrates, drain terminals may obtain stable magnitudes of currents. That is, output resistance of array substrates is higher. However, as shown by equation 1, magnitudes of output currents I_{DS} are related to width-to-length ratios W/L of array substrates. When output voltages V_{DS} reach certain levels, pinch-off points are caused to shift to the left. Sizes of L actually change to become gradually smaller. Therefore, output currents I_{DS} of array substrates gradually become larger. That is, output resistance of array substrates is not higher. Hence, input currents are not stable, and harder to be accurately controlled. How to cause array substrates to have larger output resistance and obtain stable output currents has always been a difficult problem and key to be solved in the OLED display industries.

A key problem in achieving flexible displays is how to maintain stability of array substrates. In conventional rectangular array substrates, channels are easily broken in states that screens are bent. When flexible screens are bent, film layers of array substrates may be broken due to tensile forces. According to length directions and width directions, and bending directions of array substrates being same or different, there are two possible variations in characteristics of array substrates. If length directions of array substrates are perpendicular to bending directions of array substrates, channels of array substrates may change, but may not be completely broken. Further, if length directions of array substrates are same as bending directions of array substrates, channels of array substrates may be affected much more than the first case, and may even be completely broken. These breaks may cause voltages of signals to be unable to be transmitted to pixel electrode lines, resulting in poor display.

On the other hand, even if the completely broken case is not considered, when rectangular array substrates are in bending states, characteristics of rectangular array substrates are changed more. When bending occurs, voltages of rectangular array substrates may change to different extents, resulting in changes in display performance. How to maintain that characteristics of array substrates do not change is a key problem of flexible display industries.

Annular array substrates are types of array substrates which have annular structures. Annular array substrates have advantages of having infinitely large output resistance and small changes in characteristics under bending states. However, annular array substrates have source/drain lines and gate lines which completely vertically coincide, resulting in huge parasitic capacitance. Therefore, applications of Corbino annular array substrates in high resolution display devices are restricted.

Parasitic capacitance of panels is one of factors affecting refresh rates of panels. In addition, with respect to OLEDs, because OLEDs are driven by currents, existence of parasitic capacitance affects stability of circuit signals, lowering picture quality. Distances between source electrodes/drain electrodes and gates are key parameters determining sizes of parasitic capacitance. Increasing distances between source electrodes/drain electrodes and gates can lower parasitic capacitance, which may be achieved by increasing thicknesses of gate insulating layers or thicknesses of source and drain insulating layers. However, after increasing thicknesses of gate insulating layers, in order to form same channels in active layers, voltages of gates need to be increased, which may increase power consumption and enlarge effects of parasitic capacitance. Increasing thicknesses of source and drain insulating layers also increases manufacturing cost and increases difficulty in via holes.

### SUMMARY OF INVENTION

Problems of the present disclosure are as follows. Parasitic capacitance of panels is one of factors affecting refresh rates of panels. In addition, with respect to OLEDs, because OLEDs are driven by currents, existence of parasitic capacitance affects stability of circuit signals, lowering picture quality. Distances between source electrodes/drain electrodes and gates are key parameters determining sizes of parasitic capacitance. Increasing distances between source electrodes/drain electrodes and gates can lower parasitic capacitance, which may be achieved by increasing thicknesses of gate insulating layers or thicknesses of source and drain insulating layers. However, after increasing thicknesses of gate insulating layers, in order to form same channels in active layers, voltages of gates need to be increased, which may increase power consumption and enlarge effects of parasitic capacitance. Increasing thicknesses of source and drain insulating layers also increases manufacturing cost and increases difficulty in via holes.

An object of the present disclosure is to provide an array substrate and a display device using the array substrate. By using a closed annular gate and a closed annular active layer, when a thin film transistor in the array substrate operates in a saturation region, and a channel is pinched off, a width and a length of the thin film transistor change proportionally at the same time. The result is that a width-to-length ratio is constant and output resistance is infinite, which ensures an output current to be stable.

In order to solve the aforementioned problems, the present disclosure provides an array substrate, including: a gate line; a gate insulating layer covering the gate line; an active layer disposed on the gate insulating layer; an annular source line disposed on the active layer; a circular drain line disposed on the active layer, wherein a center of the circular drain line coincides with a center of the annular source line; and an elevation layer having an annular elevation block and a circular elevation block; wherein the annular elevation block supports between the annular source line and the active layer, and the circular elevation block supports between the circular drain line and the active layer.

Further, the array substrate further includes: an insulating layer covering the active layer, the circular drain line, and the annular source line; and a pixel electrode line disposed on the insulating layer and having an end connected to the circular drain line.

Further, the insulating layer is provided with a through hole extending perpendicularly from a surface of the insulating layer to a surface of the circular drain line, and the end of the pixel electrode line passes through the through hole and is connected to the circular drain line.

Further, the circular drain line has a first circular protrusion formed corresponding to the circular elevation block, and the annular source line has an annular protrusion formed corresponding to the annular elevation block.

Further, the through hole is a circular through hole, and a diameter of the circular through hole is smaller than or equal to a diameter of the first circular protrusion.

Further, the gate insulating layer is circular, and a center of the gate insulating layer and the center of the circular drain line are located along a straight line perpendicular to the substrate.

Further, the gate line is circular, and a center of the gate line and the center of the gate insulating layer are located along a straight line perpendicular to the substrate.

Further, the gate insulating layer has a second circular protrusion formed corresponding to the gate line.

Further, the array substrate further includes: a source connection line extending from the annular source line to an edge of the gate insulating layer, wherein a portion of the source connection line located at the edge of the gate insulating layer is a source external connection portion; and a gate connection line having an end connected to the gate line, wherein the gate connection line extends from the gate line to an edge of the substrate, and a portion of the gate connection line located at the edge of the substrate is a gate external connection portion.

The present disclosure further provides a display device using the array substrate.

Advantages of an array substrate and a display device using the array substrate of the present disclosure are as follows. By using a concave-convex source/drain electrode design, a distance between a gate electrode and a source/drain electrode is enlarged. Parasitic capacitance is significantly reduced, causing the array substrate to have higher controllability.

### DESCRIPTION OF DRAWINGS

In order to describe a technical solution in embodiments more clearly, drawings required to be used by the embodiments are briefly introduced below. Obviously, the drawings in the description below are only some embodiments of the present disclosure. With respect to persons of ordinary skill in the art, under a premise that inventive efforts are not made, other drawings may be obtained based on these drawings.

FIG. 1 is a partial cross-sectional diagram of an array substrate in accordance with an embodiment of the present disclosure.

FIG. 2 is a top cross-sectional diagram of the array substrate in accordance with an embodiment of the present disclosure.

FIG. 3 is a schematic diagram of source and drain electrodes of the array substrate in accordance with an embodiment of the present disclosure.

FIG. 4 is an output characteristic curve of the array substrate in accordance with an embodiment of the present disclosure.

Components in the drawings are denoted as follows.

| | |
|---|---|
| 1 array substrate; | |
| 10 substrate; | 20 gate line; |
| 30 gate insulating layer; | 40 active layer; |
| 50 circular drain line; | 60 annular source line; |
| 70 insulating layer; | 80 pixel electrode line; |
| 90 elevation layer; | |
| 210 gate connection line; | 310 second circular protrusion; |
| 410 electron channel; | |
| 510 first circular protrusion; | |
| 610 source connection line; | 620 annular protrusion; |
| 710 through hole; | |
| 910 circular elevation block; | 920 annular elevation block; |

### DETAILED DESCRIPTION OF PREFERRED EMBODIMENTS

The description of each embodiment below refers to respective accompanying drawing(s), so as to illustrate exemplarily specific embodiments of the present disclosure that may be practiced. Directional terms mentioned in the present disclosure, such as “upper”, “lower”, “front”, “back”, “left”, “right”, “inner”, “outer”, “side”, etc., are only directions by referring to the accompanying drawings, and thus the used directional terms are used to describe and understand the present disclosure, but the present disclosure is not limited thereto.

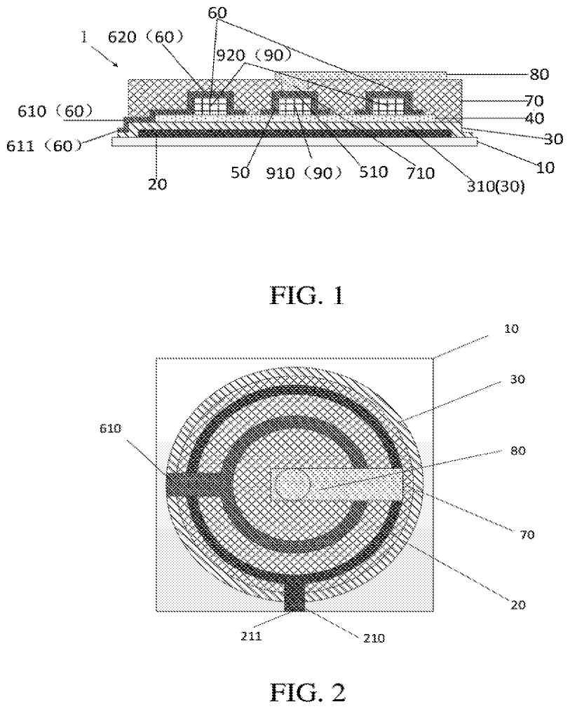

As illustrated in FIG. 1, in the present embodiment, an array substrate 1 of the present disclosure includes a substrate 10, a gate line 20, a gate insulating layer 30, an active layer 40, a circular drain line 50, an annular source line 60, an insulating layer 70, a pixel electrode line 80, and an elevation layer 90.

The gate line 20 is disposed on the substrate 10. Because when rectangular array substrates of the related art are in bending states, characteristics of rectangular array substrates are changed more, easily resulting in changes in display performance. Therefore, in the present embodiment, the gate line 20 uses a circular structure.

The gate insulating layer 30 completely covers the gate line 20. Because the gate line 20 in the present embodiment uses the circular structure, the gate insulating layer 30 has a second circular protrusion 310 formed corresponding to the gate line 20.

The active layer 40 is formed on the gate insulating layer 30. The active layer 40 uses a circular structure.

The circular drain line 50 is formed on the active layer 40. A center of the circular drain line 50 and a center of the gate line 20 are located along a straight line perpendicular to the active layer 40.

The annular source line 60 is formed on the active layer 40. The annular source line 60 surrounds the circular drain line 50. There is space between the circular drain line 50 and the annular source line 60. The space between the circular drain line 50 and the annular source line 60 corresponds to a region of the active layer 40 which is an electron channel 410.

In present embodiment, the circular drain line 50 and the annular source line 60 are disposed on a same plane, i.e. on the active layer 40. The circular drain line 50 and the annular source line 60 exhibit a concentric structure with a center of the concentric structure located at a center of the circular drain line 50. However, the present disclosure is not limited to the concentric structure. Structures such as elliptical or rectangular structures are within the scope of the present disclosure.

Referring to equation 1 in BACKGROUND OF INVENTION, and FIG. 4, FIG. 4 is an output characteristic curve of the array substrate in accordance with an embodiment of the present disclosure. Because values of a length L and a width W of the array substrate are not independent, specifically, a width-to-length ratio of the array substrate 1 is shown by equation 2:

$$\frac{W}{L} = \frac{2 π}{ln ( \frac{R 2}{R 1} )}$$

where L=R2−R1, and

$$\frac{R 2}{R 1}$$

is a ratio or an inner diameter of the annular source line 60 and a diameter of the circular drain line 50. Therefore, when the electron channel 410 in the array substrate 1 is pinched off, the width and the length of the array substrate 1 change proportionally at the same time. The result is that the width-to-length ratio is not changed. At the same time that a drain potential is increased, an output current stays unchanged. Because the gate line 20, the gate insulating layer 30, and the active layer 40 use the circular structures, the structure has advantages of having infinitely large output resistance and small changes in characteristics under bending states. When the annular array substrate structure is applied to flexible screens, the annular array substrate structure has a more stable performance than rectangular array substrate structures of the related art.

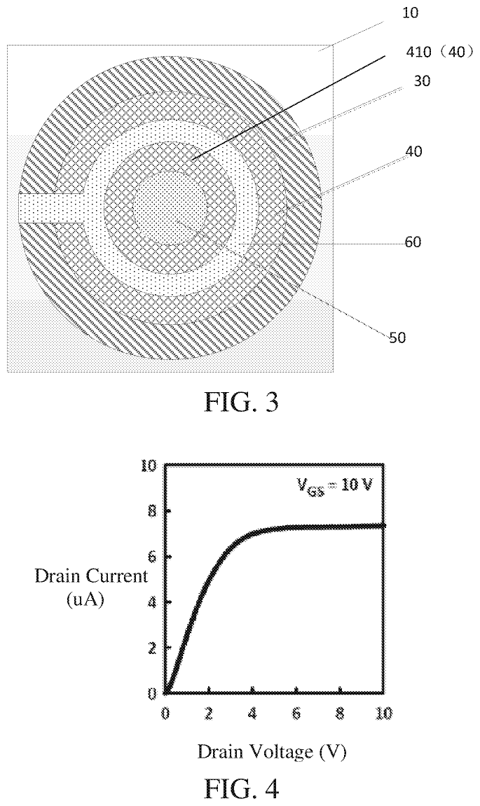

As illustrated in FIG. 3, the array substrate 1 composed of the circular drain line 50 and the annular source line 60 has the annular source line 60 (an electrode) which consumes more electrons than the circular drain line 50 (an electrode). Therefore, under a bias voltage for the drain of the array substrate 1 and the same bias voltage for drains of rectangular array substrates, the annular array substrate 1 in a saturation state has fewer charges in the channel than channels of rectangular array substrates. Therefore, few electrons are trapped because of a self-heating stress (SHS) effect. A voltage change is small. On the other hand, mechanical bending strain causes an atomic distance to increase, effectively decreasing level splitting (ΔE) of a bonding orbital and an antibonding orbital between atoms.

This is because when more electrons are excited to antibonding orbitals of the active layer 40, Fermi function values change. Increase in channel conductivity is reflected on array substrate transfer characteristics as a negatively drifted output voltage Vₜₕ of the array substrate 1. The array substrate 1 is not limited by a bending direction, and exhibits excellent stability in mechanical bending strain.

When the array substrate 1 is bent, causing the electron channel 410 to be broken, the electron channel 410 is only impacted to a small degree regardless the bending direction is left-right or up-down. That is, the array substrate 1 has good bending resistance. Parasitic capacitance in display panels is one of factors affecting refresh rates of display panels. With respect to OLEDs, because OLEDs are driven by currents, existence of parasitic capacitance affects stability of circuit signals, lowering picture quality. Therefore, in the present embodiment, the elevation layer 90 is used to increase a height of the circular drain line 50 relative to the gate line 20 and a height of the annular source line 60 relative to the gate line 20, to achieve an object of lowering parasitic capacitance.

In the present embodiment, the elevation layer 90 is divided into a circular elevation block 910 and an annular elevation block 920. The circular elevation block 910 is disposed between the circular drain line 50 and the active layer 40. A diameter of the circular elevation block 910 is smaller than the diameter of the circular drain line 50. The circular drain line 50 has a first circular protrusion 510 formed corresponding to the circular elevation block 910. A portion of the circular drain line 50 not formed as the first circular protrusion 510 is still disposed on the active layer 40, so that the circular drain line 50 is still connected with the active layer 40. Similarly, the annular elevation block 920 is disposed between the annular source line 60 and the active layer 40. A width of the annular elevation block 920 is smaller than a line width of the annular source line 60. The annular source line 60 has an annular protrusion 620 formed corresponding to the annular elevation block 920. A portion of the annular source line 60 not formed as the annular protrusion 620 is still disposed on the active layer 40, so that the annular source line 60 is still connected with the active layer 40.

The insulating layer 70 is annular, and is attached to the gate insulating layer 30. A diameter of the insulating layer 70 is smaller than a diameter of the gate insulating layer 30. There is a through hole 710 located at a center of the insulating layer 70. The through hole 710 extends perpendicularly from a surface of the insulating layer 70 to a surface of the circular drain line 50. The through hole 710 is a circular through hole. A diameter of the circular through hole 710 is smaller than or equal to a diameter of the first circular protrusion 510. The pixel electrode line 80 through the through hole 710 is electrically connected with the circular drain line 50. That is, an end of the pixel electrode line 80 passes through the through hole 710 and is connected to the circular drain line 50. In the present embodiment, a size of the through hole 710 is approximately equal to a size of the circular drain line 50. That is, the through hole 710 is circular as viewed in a top view. However, in other embodiments, shapes of the through hole 710 and the circular drain line 50 may also be different, as long as the pixel electrode line 80 can contact the circular drain line 50. An opening may also be formed on the circular drain line 50. The opening is connected to the through hole 710. In this way, a contact area between the pixel electrode line 80 and the circular drain line 50 is increased, further enhancing charging capability of the pixel electrode line 80. Similarly, the present disclosure does not limit a size and a shape of the opening, as long as the pixel electrode line 80 can contact the circular drain line 50.

As illustrated in FIGS. 1 and 2, in the present embodiment, in the substrate 1, there is also a source connection line 610. An end of the source connection line 610 is connected to an external edge of the annular source line 60, and extends from the external edge of the annular source line 60 to an edge of the gate insulating layer 30. The source connection line 610 located at the edge of the gate insulating layer 30 is exposed from the insulating layer 70. Similarly, in the substrate 1, there is also a gate connection line 210. The gate connection line 210 extends from the gate line 20 to an edge of the substrate 1. The gate connection line 210 located at the edge of the substrate 1 is exposed from the gate insulating layer 30.

The present disclosure further provides a display device. Main improvement points and features of the display device are collectively embodied on the array substrate 1. Other components of the display device such as a display layer are omitted for brevity.

The above are only the preferred embodiments of the present disclosure, and are not intended to limit the present disclosure. Any modifications, equivalent alternatives, and improvements made within the spirit and the principles of present disclosure should be included in the protection scope of the present disclosure.

1. An array substrate, comprising:
a gate line;
a gate insulating layer covering the gate line;
an active layer disposed on the gate insulating layer;
an annular source line disposed on the active layer;
a circular drain line disposed on the active layer, wherein a center of the circular drain line coincides with a center of the annular source line; and
an elevation layer having an annular elevation layer and a circular elevation layer;
wherein the annular elevation layer supports between the annular source line and the active layer, and the circular elevation layer supports between the circular drain line and the active layer.

2. The array substrate of claim 1, further comprising:
an insulating layer covering the active layer, the circular drain line, and the annular source line; and
a pixel electrode line disposed on the insulating layer and having an end connected to the circular drain line.

3. The array substrate of claim 2, wherein the insulating layer is provided with a through hole extending perpendicularly from a surface of the insulating layer to a surface of the circular drain line, and the end of the pixel electrode line passes through the through hole and is connected to the circular drain line.

4. The array substrate of claim 3, wherein the circular drain line has a first circular protrusion formed corresponding to the circular elevation layer, and the annular source line has an annular protrusion formed corresponding to the annular elevation layer.

5. The array substrate of claim 4, wherein the through hole is a circular through hole, and a diameter of the circular through hole is smaller than or equal to a diameter of the first circular protrusion.

6. The array substrate of claim 1, wherein the gate insulating layer is circular, and a center of the gate insulating layer and the center of the circular drain line are located along a straight line perpendicular to the substrate.

7. The array substrate of claim 6, wherein the gate line is circular, and a center of the gate line and the center of the gate insulating layer are located along a straight line perpendicular to the substrate.

8. The array substrate of claim 7, wherein the gate insulating layer has a second circular protrusion formed corresponding to the gate line.

9. The array substrate of claim 1, further comprising:
a source connection line extending from the annular source line to an edge of the gate insulating layer, wherein a portion of the source connection line located at the edge of the gate insulating layer is a source external connection portion; and
a gate connection line having an end connected to the gate line, wherein the gate connection line extends from the gate line to an edge of the substrate, and a portion of the gate connection line located at the edge of the substrate is a gate external connection portion.

10. A display device using the array substrate of claim 1.

11. A display device using the array substrate of claim 2.

12. A display device using the array substrate of claim 3.

13. A display device using the array substrate of claim 4.

14. A display device using the array substrate of claim 5.

15. A display device using the array substrate of claim 6.

16. A display device using the array substrate of claim 7.

17. A display device using the array substrate of claim 8.

18. A display device using the array substrate of claim 9.
